(19) United States
(12) Patent Application Publication
(10) Pub. No.: US 2025/0204066 A1
(43) Pub. Date: Jun. 19, 2025

(54) OPTICAL SENSOR PACKAGING AND METHOD OF MANUFACTURE

(71) Applicant: STMicroelectronics International N.V., Geneva (CH)

(72) Inventor: Jing-En LUAN, Singapore (SG)

(73) Assignee: STMicroelectronics International N.V., Geneva (CH)

(21) Appl. No.: 18/956,678

(22) Filed: Nov. 22, 2024

Related U.S. Application Data
(60) Provisional application No. 63/612,125, filed on Dec. 19, 2023.

(51) Int. Cl. H01L 27/146

(52) U.S. Cl. CPC H10F 39/804; H10F 39/024; H10F 39/026; H10F 39/8063; H10F 39/811

(57) ABSTRACT

A package substrate panel includes die mounting zones which are separated from each other by inter-die mounting zones. An optical integrated circuit die having a sacrificial cover over a location of an optical sensor is mounted at each die mounting zone. An encapsulating resin material is molded on the package substrate panel to encapsulate the optical integrated circuit die and at least surround the sacrificial cover to form an encapsulated panel structure. The sacrificial covers are then removed to expose the optical sensors of the optical integrated circuit dies. The encapsulated panel structure is cut at the inter-die mounting zones to singulate the encapsulated panel structure into optical integrated circuit packages.

### CROSS REFERENCE TO RELATED APPLICATIONS

This application claims priority to United States Provisional Application for Patent No. 63/612,125, filed Dec. 19, 2023, the disclosure of which is incorporated herein by reference.

### TECHNICAL FIELD

The present invention generally relates to the packaging of optical integrated circuits.

### BACKGROUND

Reference is made to FIG. 1 which shows a cross-sectional view of an optical integrated circuit package 10. The package 10 includes a package substrate 12, for example in the form of a multilayer board 14 (for example, of printed circuit board type) including an interconnection network 16 (formed of wire lines and vias) that electrically connects front electrical pads 18 to rear electrical pads 20. The rear electrical pads 20 may comprise, for example, parts of a redistribution layer (RDL). Although not explicitly shown, it will be noted that the front and rear surfaces of the package substrate 12 may include a solder masking layer with openings at the locations of the pads 18 and 20. The rear electrical pads 20 may comprise, for example, support pads for pillars 21p or balls 21b (in a ball grid array (BGA) type package). The rear electrical pads 20 may comprise, for example, connection solder pads (in a land grid array (LGA) type package).

An optical integrated circuit die 22 is mounted to the upper surface of the package substrate 12 using a suitable adhesive material (for example, a die attach film (DAF)). The optical integrated circuit die 22 includes, associated with a surface (for example, a front surface) opposite the surface (for example, a rear surface) attached to the package substrate 12, an optical sensor 24 (for example, formed by an array of photosensitive elements such as photodiodes) and a plurality of electrical connection die bonding pads 26. The electrical connection die bonding pads 26 of the optical integrated circuit die 22 are electrically connected to the front electrical pads 18 of the package substrate 12 using bonding wires 28.

An adhesive ring 30 is provided at the front surface of the optical integrated circuit die 22 to encircle (i.e., surround) the optical sensor 24. The adhesive ring 30 is positioned in a gap area 32 at the front surface of the optical integrated circuit die 22 between the periphery of the optical sensor 24 and the electrical connection die bonding pads 26. A diffractive optical element (DOE) 34 (for example, including one or more of an optical lens and an optical filter (for example, an infrared (IR) filter), and having a form of a flat plate) is attached to the optical integrated circuit die 22 using the adhesive ring 30. The DOE 34 is positioned to extend over the optical sensor 24 of the optical integrated circuit die 22. The adhesive ring 30 may include additives such as spacer balls to control spacing of the bottom surface of the DOE 34 from the optical sensor 24 (for example, in situations where an array of microlens structures is provided over the optical sensor 24). The adhesive ring 30 also forms a dam structure that prevents a packaging encapsulant material used to form the encapsulating resin package body 36 from seeping over and covering part of the optical sensor 24. In an embodiment, the adhesive ring 30 may comprise an epoxy bead that is used to adhere the DOE 34 to the front surface of the optical integrated circuit die 22. The encapsulating resin package body 36 seals against the peripheral side edges of the DOE 34, encapsulating the optical integrated circuit die 22 and bonding wires 28, and attaches to the package substrate 12.

Due to advances in the technology node used to fabricate the optical integrated circuit die 22, the size of the gap area 32 at the front surface of the optical integrated circuit die 22 between the periphery of the optical sensor 24 and the electrical connection die bonding pads 26 is shrinking. In many packaging implementations, this gap area is not longer large/wide enough to accommodate placement of the adhesive ring 30 without risk of contaminating the optical sensor 24 or risking damage to the bonding wires at the connection to the electrical connection die bonding pads 26 of the optical integrated circuit die 22.

There is accordingly a need in the art for a new packaging process and optical sensor package.

### SUMMARY

In an embodiment, a method comprises: providing a package substrate panel including a plurality of die mounting zones which are separated from each other by inter-die mounting zones; mounting, at each die mounting zone, an optical integrated circuit die having a sacrificial cover over a location of an optical sensor; molding an encapsulating resin material on the package substrate panel to encapsulate the optical integrated circuit die and at least surround the sacrificial cover to form an encapsulated panel structure; removing the sacrificial covers to expose the optical sensors of the optical integrated circuit dies; and cutting the encapsulated panel structure at the inter-die mounting zones to singulate the encapsulated panel structure into a plurality of optical integrated circuit packages.

The removal of the sacrificial covers forms a through opening in the encapsulating resin material of the encapsulated panel structure over each optical sensor. Each through opening is then covered with a diffractive optical element. The diffractive optical element may be adhesively mounted to an upper surface of the encapsulated panel structure.

The molding of the encapsulating resin material on the package substrate panel forms a sub-opening in the encapsulating resin material of the encapsulated panel structure over each sacrificial cover. Removal of the sacrificial cover forms a further sub-opening in the encapsulating resin material of the encapsulated panel structure over each optical sensor. Each further sub-opening is covered with a diffractive optical element. The formation of the sub-opening defines a ledge surrounding each sacrificial cover, and the diffractive optical element is adhesively mounted to the ledge.

In an embodiment, an optical integrated circuit package comprises: a package substrate; an optical integrated circuit die having an optical sensor and electrical connection die bonding pads; an encapsulating resin package body on the package substrate and which encapsulates the optical integrated circuit die and the electrical connection die bonding pads of the optical integrated circuit die; wherein said encapsulating resin package body includes a through opening which exposes the optical sensor of the optical integrated circuit die; and a diffractive optical element mounted to a surface of the encapsulating resin package body to cover over the through opening.

In an embodiment, said through opening comprises: a first sub-opening having a first cross-sectional area; a second sub-opening having a second cross-sectional area larger than the first cross-sectional area; wherein the first and second sub-openings are aligned; wherein the second sub-opening defines a ledge surrounding the first-sub opening; and wherein the ledge is the surface of the encapsulating resin package body to which the diffractive optical element is mounted.

### BRIEF DESCRIPTION OF THE DRAWINGS

For a better understanding of the embodiments, reference will now be made by way of example only to the accompanying figures in which:

FIG. 1 shows a cross-sectional view of an optical integrated circuit package;

FIG. 2 shows a cross-sectional view of an optical integrated circuit package;

FIG. 3 shows a cross-sectional view of an optical integrated circuit package;

FIGS. 4A-4M illustrate steps in a process for manufacturing the package as shown in FIG. 2; and

FIG. 5 shows a cross-sectional view of an optical integrated circuit package.

### DETAILED DESCRIPTION

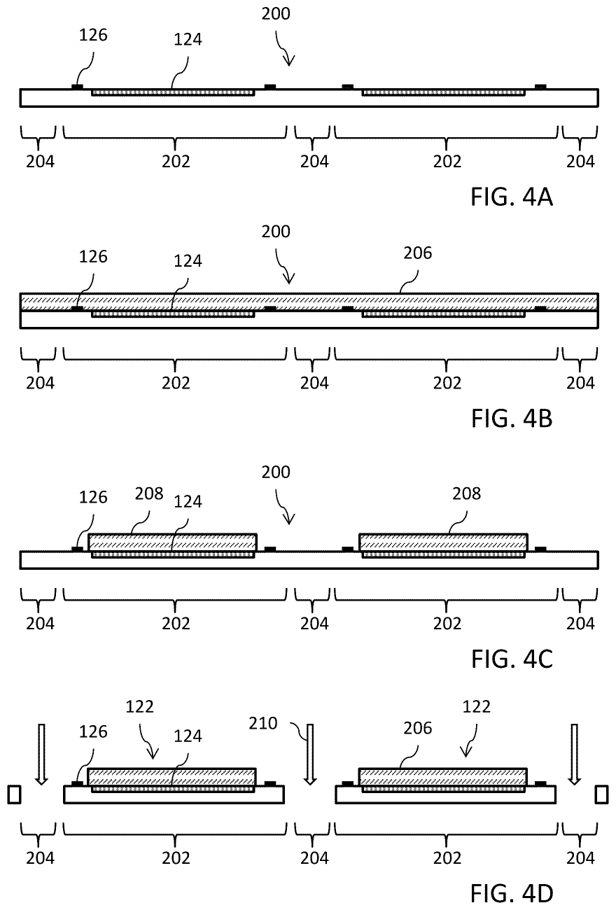

Reference is made to FIG. 2 which shows a cross-sectional view of an optical integrated circuit package 110. The package 110 includes a package substrate 112, for example in the form of a multilayer board 114 (for example, of printed circuit board type) including an interconnection network 116 (formed of wire lines and vias) that electrically connects front electrical pads 118 to rear electrical pads 120. The rear electrical pads 120 may comprise, for example, parts of a redistribution layer (RDL). Although not explicitly shown, it will be noted that the front and rear surfaces of the package substrate 112 may include a solder masking layer with openings at the locations of the pads 118 and 120. The rear electrical pads 120 may comprise, for example, support pads for pillars 121p or balls 121b (in a ball grid array (BGA) type package). The rear electrical pads 120 may comprise, for example, connection solder pads (in a land grid array (LGA) type package).

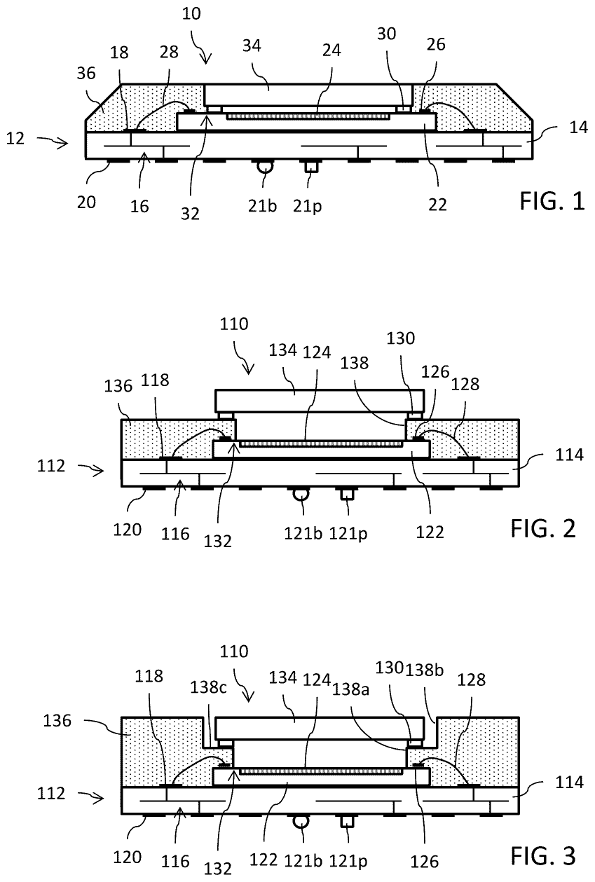

An optical integrated circuit die 122 is mounted to the upper surface of the package substrate 112 using a suitable adhesive material (for example, a die attach film (DAF)). The optical integrated circuit die 122 includes, associated with a surface (for example, a front surface) opposite the surface (for example, a rear surface) attached to the package substrate 112, an optical sensor 124 (for example, formed by an array of photosensitive elements such as photodiodes) and a plurality of electrical connection die bonding pads 126. It will be noted that the size of the gap area 132 at the front surface of the optical integrated circuit die 122 between the periphery of the optical sensor 124 and the electrical connection die bonding pads 126 in FIG. 2 is much smaller than the size of the gap area 32 at the front surface of the optical integrated circuit die 22 between the periphery of the optical sensor 24 and the electrical connection die bonding pads 26 in FIG. 1. The electrical connection die bonding pads 126 of the optical integrated circuit die 122 are electrically connected to the front electrical pads 118 of the package substrate 112 using bonding wires 128.

An encapsulating resin package body 136 encapsulates the optical integrated circuit die 122, the electrical connection die bonding pads 126 at the outer periphery of the front surface of the optical integrated circuit die 122, the bonding wires 128, and attaches to the package substrate 112. A through opening 138 is provided in the encapsulating resin package body 136 that exposes the optical sensor 124 of the optical integrated circuit die 122. The through opening 138 has a cross-sectional area that is slightly larger than the cross-sectional area of the optical sensor 124 (but not large enough to expose to the electrical connection die bonding pads 126 and/or bonding wires 128 which remain encapsulated within the encapsulating resin package body 136). An adhesive ring 130 is mounted to a front surface of the encapsulating resin package body 136 to encircle (i.e., surround) the through opening 138. A diffractive optical element (DOE) 134 (for example, including one or more of an optical lens and an optical filter (for example, an infrared (IR) filter), and having a form of a flat plate) is attached to the front surface of the encapsulating resin package body 136 using the adhesive ring 130. The DOE 134 is positioned to extend over the through opening 138 and the optical sensor 124 of the optical integrated circuit die 122.

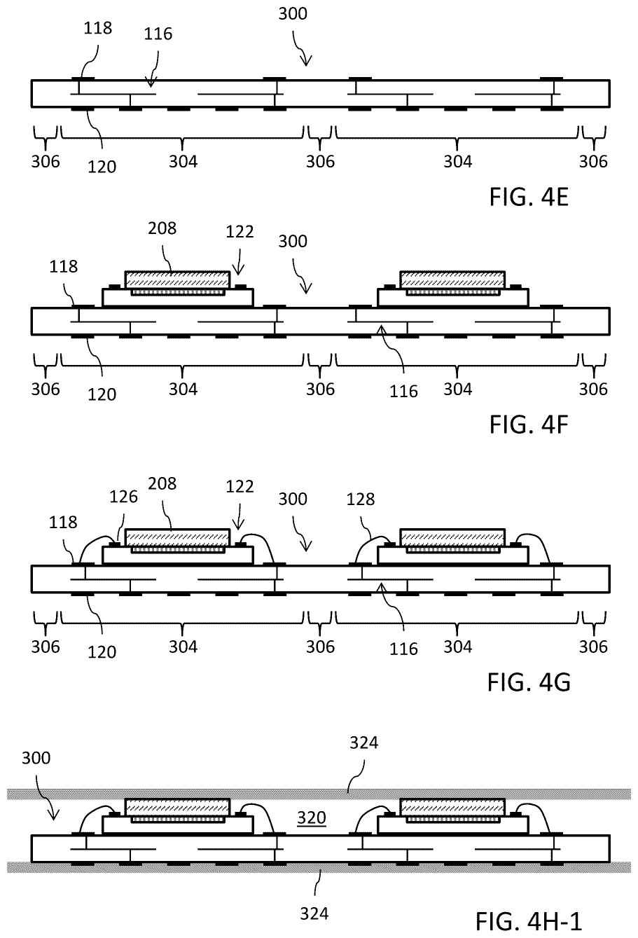

Reference is made to FIG. 3 which shows a cross-sectional view of an optical integrated circuit package 210. The package 210 is similar to the package 110 of FIG. 2. Like references in FIGS. 2 and 3 refer to same or similar components. The package 210 differs from the package 110 of FIG. 2 in the shape and configuration of the encapsulating resin package body 136 and the placement of the adhesive ring 130 and DOE 134. The through opening 138 in the encapsulating resin package body 136 in the package 210 of FIG. 3 comprises a first sub-opening 138a having a first cross-sectional area that is slightly larger than the cross-sectional area of the optical sensor 124 (but not large enough to expose to the electrical connection die bonding pads 126 and/or bonding wires 128 which remain encapsulated within the encapsulating resin package body 136) and a second sub-opening 138b having a second cross-sectional area that is larger than the first cross-sectional area (and furthermore is slightly larger than the cross-sectional area of the DOE 134, and which may be larger than the area of the optical integrated circuit die 122). The first and second sub-openings 138a, 138b are aligned with each other (for example, may be concentric openings). Because of the alignment of the sub-openings 138a, 138b and the difference in cross-sectional area sizes for the sub-openings 138a, 138b, the overall through opening 138 includes a ledge 138c that peripherally surrounds the first sub-opening 138a. The adhesive ring 130 is mounted to the ledge 138c of the encapsulating resin package body 136 to encircle (i.e., surround) the first sub-opening 138a. The DOE 134 is mounted to the ledge 138c using the adhesive ring 130. The DOE 134 is accordingly positioned within the second sub-opening 138b and extends over the first sub-opening 138a and the optical sensor 124 of the optical integrated circuit die 122. In an embodiment, the adhesive ring 130 may comprise an epoxy bead or an adhesive film layer.

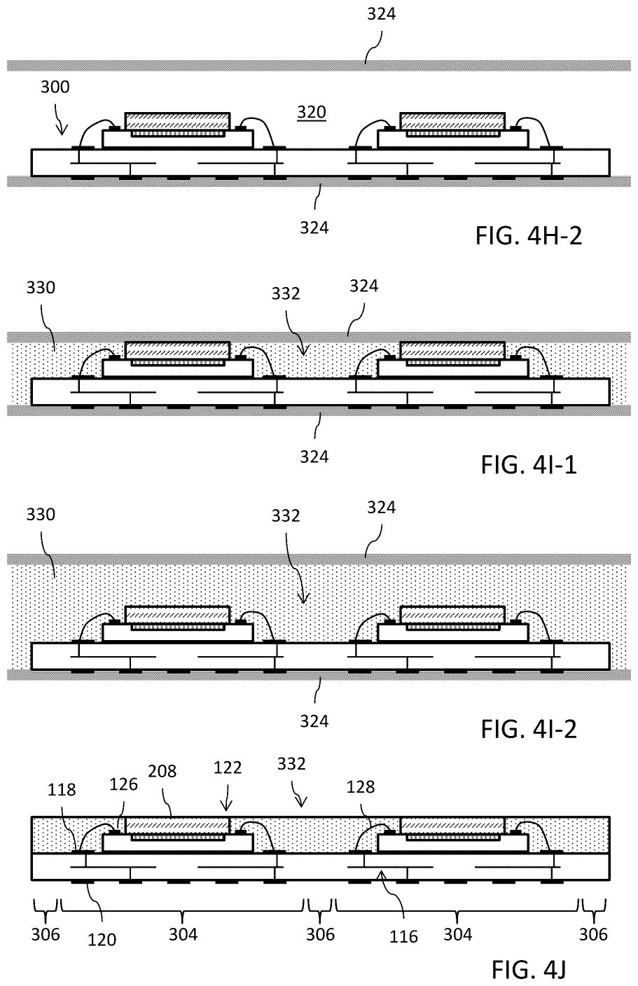

Reference is now made to FIGS. 4A-4M which illustrate steps in a process for manufacturing the package 110 as shown in FIG. 2.

FIG. 4A—an integrated circuit wafer 200 includes a plurality of integrated circuits 202 which are separated from each other by scribe lines 204. FIG. 4A illustrates a portion of the wafer 200 containing two such circuits 202. The wafer 200 is fabricated using conventional front end of line (FEOL), middle end of line (MEOL), and back end of line (BEOL) processing operations. Each integrated circuit 202 includes, associated with a surface (for example, a front surface), an optical sensor 124 (for example, formed by an array of photosensitive elements) and a plurality of electrical connection die bonding pads 126. The front surface of the wafer 200 may, for example, be provided by upper passivation layer structure.

FIG. 4B—a layer 206 of photoresist material is deposited on the front surface of the wafer 200.

FIG. 4C—conventional lithographic processing techniques are used to lithographically pattern the layer 206 to form sacrificial covers 208 over the optical sensors 124. The lithographic processing techniques may, for example, comprise: a soft bake of the layer 206, the formation of a pattern mask over the layer 206 where the pattern mask includes openings at the locations of the optical sensors 124, exposure of the layer 206 through the mask openings, and development of the layer 206 to remove unexposed portions of the layer 206 while leaving the exposed portions of the layer in place to form the sacrificial covers 208.

FIG. 4D—the wafer 200 is cut at the scribe lines 204 to singulate (also referred to in the art as dice) the wafer 200 into a plurality of optical integrated circuit dies 122. The cutting of the scribe lines 204 during singulation (dicing) of the wafer 200 may, for example, be made using a saw or laser (schematically indicated by arrow 210). This operation does not disturb the sacrificial covers 208 which provide a sealed protection over the optical sensors 124 to ensure that debris from the singulation process does not contaminate the optical sensors 124.

FIG. 4E—a package substrate panel 300 is a multilayer board structure 302 including a plurality of die mounting zones 304 which are separated from each other by inter-die mounting zones 306. Each die mounting zone 304 includes an interconnection network 116 (formed by connecting lines and vias) that electrically connects front electrical pads 118 to rear electrical pads 120. The rear electrical pads 120 may comprise, for example, parts of a redistribution layer (RDL). The rear electrical pads 120 may comprise, for example, support pads for pillars or balls (in a ball grid array (BGA) type package). The rear electrical pads 120 may comprise, for example, connection solder pads (in a land grid array (LGA) type package).

FIG. 4F—an optical integrated circuit die 122 with a sacrificial cover 208 over the location of the optical sensor 124, as produced using the steps of FIGS. 4A-4D, is then mounted to the upper surface of the package substrate panel 300 at each die mounting zone 304. The mounting of each optical integrated circuit die 122 with cover 208 can be accomplished, for example, using a pick and place process with a suitable adhesive material (for example, a die attach film (DAF)) positioned between a bottom surface of the die 122 and the top surface of the package substrate panel 300.

FIG. 4G—a wirebonding process is then performed to wirebond each optical integrated circuit die 122 with cover 208 to the package substrate panel 300. The wirebonding process forms bonding wires 128 that electrically connect the electrical connection die bonding pads 126 of the optical integrated circuit die 122 to the front electrical pads 118 of the interconnection network 116.

FIGS. 4H-1 and 4H-2—the package substrate panel 300 with mounted optical integrated circuit dies 122, each die having a sacrificial cover 208, is then placed within the cavity 320 of a mold 324. As shown in FIG. 4H-1, an upper mold part of the mold 324 is placed in contact with the upper surfaces of the sacrificial covers 208 and a lower mold part of the mold 324 is placed in contact with the bottom surface of the package substrate panel 300. Alternatively, as shown in FIG. 4H-2, only the bottom surface of the package substrate panel 300 is placed in contact with the lower mold part of the mold 324.

FIGS. 4I-1 and 4I-2—the cavity 320 of the mold 324 is then filled with an encapsulating resin material 330 to produce an encapsulated panel structure 332.

The encapsulated panel structure 332 is removed from the mold 324. For the embodiment as in FIGS. 4H-2 and 4I-2, the encapsulating resin material 330 covering the sacrificial covers 208 is removed using a grinding or polishing operation so that the upper surfaces of the sacrificial covers 208 are exposed from the encapsulating resin material 330. Similarly, the grinding or polishing operation may be used to remove unwanted encapsulating resin material 330 (for example, in the form of molding flash) which may be present on the upper surfaces of the sacrificial covers 208 when molding using the embodiment as in FIGS. 4H-1 and 4I-1.

Although a two piece mold 324 is shown as a primary embodiment, the molding operation performed to encapsulate the package substrate panel 300 with mounted optical integrated circuit dies 122, each die having a sacrificial cover 208, and form the encapsulated panel structure 332 may instead be implemented using a one piece mold of the open top type which forms a dam surrounding the package substrate panel 300. The cavity of the one piece mold of the open top type is then filled with the encapsulating resin material 300. If necessary, the top of the encapsulated panel structure 332, after being removed from the mold, may be treated with a grind or surface polish to provide a planar upper surface and remove unwanted portions of encapsulating resin material which may be present on the upper surfaces of the sacrificial covers 208.

The resulting encapsulated panel structure 332 is shown in FIG. 4J.

It will be noted that at this point in the process, support pads for pillars 121p or balls 121b (in a ball grid array (BGA) type package) may be attached to the rear electrical pads 120.

FIG. 4K—the sacrificial covers 208 are then removed from the encapsulated panel structure 332 using a resist stripping process. This leaves a through opening 138 in the encapsulated panel structure 332 at each optical integrated circuit die 122 that exposes the optical sensor 124.

FIG. 4L—a DOE 134 is then mounted to the upper surface of the encapsulating resin material 330 of the encapsulated panel structure 332 to cover each through opening 138. In an embodiment, this mounting of the DOE 134 is achieved through the use of an adhesive ring 130 that surrounds the through opening 138. The adhesive ring 130 may comprise, for example, an epoxy bead or an adhesive film layer.

FIG. 4M—the encapsulated panel structure 332 is then cut at the locations of the inter-die mounting zones 306 to singulate (also referred to in the art as dice) the encapsulated panel structure 332 into a plurality of optical integrated circuit packages 110. The cutting of the inter-die mounting zones 306 during singulation (dicing) of the encapsulated panel structure 332 may, for example, be made using a saw or laser (schematically indicated by arrow 210).

The process of FIGS. 4A-4M may also be used, with some modification at the stage of molding the encapsulating resin material 300 to form the encapsulated panel structure 332 and produce the second sub-opening 138b, to produce the optical integrated circuit package 210. For example, the upper mold part of the mold 324 may include a projection in the shape the second sub-opening 138b that is aligned with the location of each sacrificial cover 208 in the package substrate panel 300 with mounted optical integrated circuit dies 122. The filling of the mold with the encapsulating resin material 300 around the projections in the upper mold part of the mold 324 forms the second sub-openings 138b, and the subsequent removal of the sacrificial covers 208 forms the first sub-openings 138b. The alignment of the projection with the location of the sacrificial cover 208 and the difference in cross-sectional area of the projections relative the cross-sectional area of the sacrificial covers 208 defines the ledges 138c.

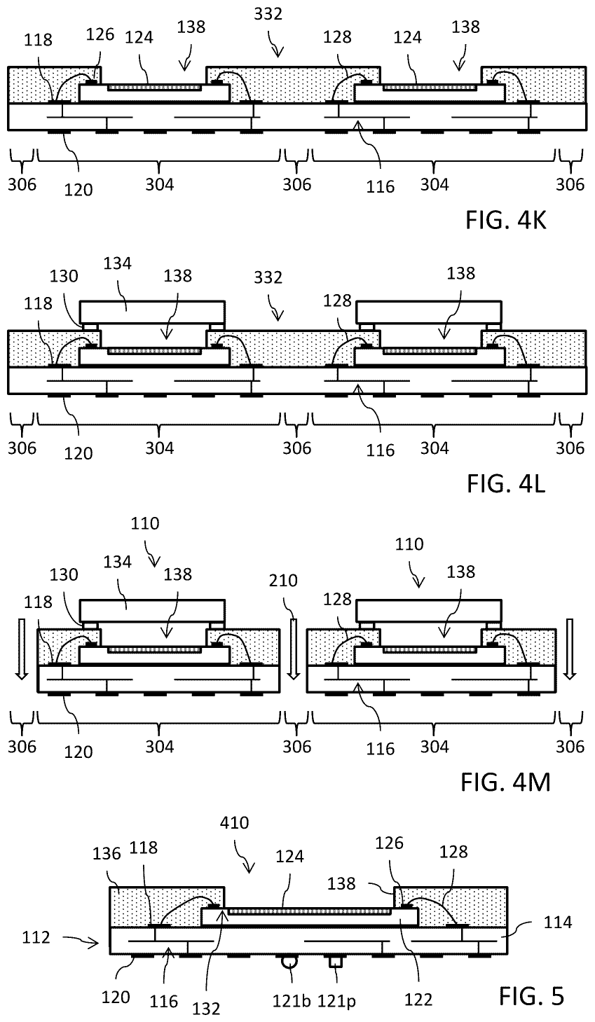

In an alternative embodiment, the step of FIG. 4L may be omitted to produce a glass-less (i.e., no DOE 134) optical integrated circuit package 410 as shown in in FIG. 5.

The optical integrated circuit packages of FIGS. 2, 3 and 5 present a number of advantages over the package of FIG. 1 including: a) support for packaging of optical integrated circuit dies where the size of the gap area at the front surface of the optical integrated circuit die between the periphery of the optical sensor and the electrical connection die bonding pads is reduced; b) support of packages having smaller form factors and production of packages occupying smaller areas; and c) protection of the optical sensor with the sacrificial cover during the packaging process. With respect to the optical integrated circuit packages of FIGS. 2 and 3, a further advantage over the package of FIG. 1 is that the DOE is mounted to the encapsulating body instead of the optical integrated circuit die and thus less stress is directly applied to the die since the material of the encapsulating body functions as a stress buffer.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
providing a package substrate panel including a plurality of die mounting zones which are separated from each other by inter-die mounting zones;
mounting, at each die mounting zone, an optical integrated circuit die having a sacrificial cover over a location of an optical sensor;
molding an encapsulating resin material on the package substrate panel to encapsulate the optical integrated circuit die and at least surround the sacrificial cover to form an encapsulated panel structure;
removing the sacrificial covers to expose the optical sensors of the optical integrated circuit dies; and
cutting the encapsulated panel structure at the inter-die mounting zones to singulate the encapsulated panel structure into a plurality of optical integrated circuit packages.

2. The method of claim 1, wherein each optical integrated circuit die includes a plurality of electrical connection die bonding pads, and wherein the encapsulating resin material covers the electrical connection die bonding pads.

3. The method of claim 2, further comprising wirebonding the electrical connection die bonding pads of the optical integrated circuit dies to front electrical pads of the package substrate panel.

4. The method of claim 3, wherein the encapsulating resin material further encapsulates bonding wires formed by said wirebonding.

5. The method of claim 1, wherein removing the sacrificial covers forms a through opening in the encapsulating resin material of the encapsulated panel structure over each optical sensor, and further comprising covering each through opening with a diffractive optical element.

6. The method of claim 5, wherein covering comprises adhesively mounting the diffractive optical element to an upper surface of the encapsulated panel structure.

7. The method of claim 5, wherein the diffractive optical element comprises one or more of a filter and a lens.

8. The method of claim 1, wherein molding the encapsulating resin material on the package substrate panel forms a sub-opening in the encapsulating resin material of the encapsulated panel structure over each sacrificial cover, and wherein removing the sacrificial cover forms a further sub-opening in the encapsulating resin material of the encapsulated panel structure over each optical sensor, and further comprising covering each further sub-opening with a diffractive optical element positioned within the sub-opening.

9. The method of claim 8, wherein formation of the sub-opening defines a ledge surrounding each sacrificial cover, and wherein covering comprises adhesively mounting the diffractive optical element to the ledge.

10. The method of claim 8, wherein the diffractive optical element comprises one or more of a filter and a lens.

11. The method of claim 1, further comprising:
providing an integrated circuit wafer including a plurality of integrated circuits which are separated from each other by scribe lines;
wherein each integrated circuit includes the optical sensor;
forming the sacrificial cover over the location of each optical sensor; and
cutting the integrated circuit wafer at the scribe lines to singulate the integrated circuit wafer into a plurality of optical integrated circuit dies.

12. An optical integrated circuit package, comprising:
a package substrate;
an optical integrated circuit die having an optical sensor and electrical connection die bonding pads;
an encapsulating resin package body on the package substrate and which encapsulates the optical integrated circuit die and the electrical connection die bonding pads of the optical integrated circuit die;
wherein said encapsulating resin package body includes a through opening which exposes the optical sensor of the optical integrated circuit die; and
a diffractive optical element mounted to a surface of the encapsulating resin package body to cover over the through opening.

13. The optical integrated circuit package of claim 12, wherein said through opening comprises:
a first sub-opening having a first cross-sectional area;
a second sub-opening having a second cross-sectional area larger than the first cross-sectional area;
wherein the first and second sub-openings are aligned;
wherein the second sub-opening defines a ledge surrounding the first-sub opening; and
wherein the ledge is the surface of the encapsulating resin package body to which the diffractive optical element is mounted.

14. The optical integrated circuit package of claim 12, further comprising bonding wires that electrically connect the electrical connection die bonding pads of the optical integrated circuit die to front electrical pads of the package substrate, wherein said bonding wired are encapsulated within the encapsulating resin package body.
